(19) United States
(12) Patent Application Publication
(10) Pub. No.: US 2006/0240260 A1
(43) Pub. Date: Oct. 26, 2006

(54) Cover, mobile communications apparatus and method for producing a coated cover

(75) Inventors: Markku Heino, Espoo (FI); Nina M. Koskinen, Helsinki (FI); Ari E. Oikarinen, Helsinki (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 11/403,528

(22) Filed: Apr. 13, 2006

(30) Foreign Application Priority Data
Apr. 15, 2005 (FI) U20050139

(51) Int. Cl. H05H 1/24; C23C 16/00; C23C 16/26; B32B 9/00

(52) U.S. Cl. 428/408; 427/569; 427/249.7

(57) ABSTRACT

The invention relates to a cover, a mobile communications apparatus and a method for producing a coated cover for an electronic apparatus. According to the invention at least a part of the cover is coated with a DLC-coating, also called an amorphous diamond coating.

### TECHNICAL FIELD OF THE INVENTION

The invention relates to a cover, a mobile communications apparatus and a method for producing a coated cover for an electronic apparatus. The invention relates in particular to a cover, which is coated with a novel non-metallic coating.

### PRIOR ART

It is known to coat plastic parts, such as the covers for mobile communications apparatuses and other portable apparatuses with metals, metal alloys or with other coatings. One coating method is disclosed in the International Patent Publication WO 03/077510 A1 of the assignee. By means of a coating it is usually desired to improve the appearance of product or then some other functional property is sought after, such as wear resistance, improved tactile feel, removal of slipperiness or, for example, certain electrical conductivity. A desired level of the above-mentioned properties is not always attained by means of methods of prior art. There is a need for more inexpensive and more easily achievable reflecting surfaces of optical parts in electronic apparatuses and for ESD (electrical static discharge) and EMI (electromagnetic interference) protection for products to be coated. A problem related to some coatings of prior art, and in particular to some metallic coatings, is their poor recyclability and non-degradability in nature of waste created thereby. Typical methods utilized in coating of prior art are, for example, chemical or physical vapor phase growth method, vacuum evaporation or electrolysis. These methods often require large amounts of toxic additives and solvents.

### AIM AND DESCRIPTION OF THE INVENTION

It is an aim of the present invention, among other things, to reduce or even eliminate the above-mentioned problems of the prior art.

The aim of the present invention is in particular to provide a solution by means of which certain visual or other functions can be made available to the cover for a portable electronic apparatus, such as a mobile communications apparatus or other electronic apparatus.

The aim of the present invention is in particular to provide a coated cover for a mobile communications apparatus or other electronic apparatus that is environmentally friendly and easily recyclable.

In order to attain the aims mentioned above a mobile communications apparatus, a cover for an electronic apparatus as well as a method for producing a coated cover for an electronic apparatus according to the invention are characterized by what is presented in the characterizing parts of the enclosed independent claims.

The embodiments and advantages mentioned in this text apply, where applicable, to the mobile communications apparatus, the cover for electronic apparatus as well as to the method for producing a coated cover for an electronic apparatus, although this is not always mentioned separately. The characteristics of the dependent claims related to the cover are possible characteristics also for the mobile communications apparatus and method for producing a coated cover for an electronic apparatus.

By an electronic apparatus is meant, for example, a portable electronic apparatus. By a portable electronic apparatus is meant, for example, mobile phones, such as cellular radiophones, wireless radiophones and personal communicators, laptop computers, PDA-apparatuses (Personal Digital Assistant), cameras and portable music players. A portable electronic apparatus can also refer to a radio, game console, television, DVD-player or a corresponding apparatus or some combination of the above-mentioned apparatuses.

By a cover is meant a part arranged in a fixed manner in a mobile communications apparatus or in another electronic apparatus during its normal use. The cover is typically intended to be visible during normal use to cover and protect the technical parts of the apparatus, which remain underneath the cover, which parts are referred to as the frame of the apparatus. The cover can cover the frame of the apparatus nearly completely. The frame may have a front part, i.e. a mainly a functional part, through which the interface of the apparatus is typically accessed. The cover may also comprise a rear part, usually on an opposite side of the apparatus in relation to the functional part. There is often a side part or side parts of the cover between the front part and rear part, which side parts cover the frame of the apparatus over an area between the front and rear parts. The cover comprises typically an outer surface, which is intended to be visible and/or to be touched during use of the electronic apparatus, and an inner surface, which is intended to remain mainly hidden during use of the apparatus. Typically, the front part, rear part and side part of the cover define the outer surface of the apparatus. The front part, rear part and side part can partly be of the one and the same part or completely separate parts. The cover may comprise of several parts.

The cover may be fastened to the apparatus in a relatively fixed manner or it can be easily detachable and reassemblable even for a normal consumer. Such an easily detachable and fastenable cover is called a switch cover.

A typical cover for an electronic apparatus comprises a basic part, for example a part of the cover made of plastic or metal, and a coating, by which at least a part of the basic part has been coated. In a typical embodiment of the invention a special non-metallic diamond like coating is arranged onto the parts of the electronic apparatus made of for example plastic, metal, fabric or leather, which coating is referred to in this text with the abbreviation DLC-coating (DLC=Diamond Like Carbon). A DLC-coating can also be called an amorphous diamond coating. By means of this coating new properties related to appearance and certain other functional properties are achieved.

A typical mobile communications apparatus and portable electronic apparatus according to the invention comprise at least one cover according to the invention.

In one embodiment of the invention the DLC-coating is arranged in particular on plastic or other non-metallic surfaces to give them new functional properties.

By DLC-coating on the cover of an electronic apparatus typically is meant that coating is applied on the cover over a uniform area with a substantial size. According to the invention DLC-coating may arranged over a uniform area, for example, having the size of at least 0.1 cm², 0.2 cm², 0.3 cm^{2, 0.5} cm², 1 cm², 4 cm², 10 cm². According to the invention DLC-coating may also be arranged over a uniform area, for example, having the size of 0.1 cm²-100 cm² or 0.1 cm²-10 cm² or 0.1 cm²-1 cm².

In a typical coating method according to the invention coal plasma is produced from solid graphite by means of an arc discharge method known per se. In this method, coal plasma is accelerated between two electrodes in order to provide a large amount of kinetic energy to the coal ions. High-energy coal ions adhere to the surface of the part to be coated by penetrating the part to be coated. Coal ions form on the surface of the part to be coated an amorphous diamond structure, i.e. a DLC-coating.

In a typical embodiment of the invention the cover for a portable electronic apparatus, such as a mobile phone, is coated at least nearly completely with a coating according to the invention.

A cover according to one embodiment of the invention to be coated according to the invention can be manufactured by injection molding in the same manner as the covers of prior art. For example, in a typical manufacturing method of a plastic cover, first a polymer mixture is injection molded to form the cover of a mobile communications apparatus or other portable electronic apparatus. When the cover is ready to be coated, it is coated with a DLC-coating according to the invention. In a manufacturing method of a mobile communications apparatus or other portable electronic apparatus according to the invention, the other parts of the apparatus, such as the frame, are manufactured separately by means of a method known per se, and the cover according to the invention is installed around these other parts. In the manufacture of covers and apparatuses according to the invention largely the same apparatuses can be used, among other things moulds, as in the manufacture of current covers and apparatuses.

In one embodiment of the invention the cover is intended to be used together with such an electronic apparatus, the frame of which comprises a number of function keys for using the apparatus and a display for displaying information related to the operation of the apparatus, and the cover enfolds said components at least partly within itself. The cover has thus at least one first opening for viewing said display and at least one second opening, through which function keys fit freely. Such a cover may be a switch cover, which can replace the detachable cover of the portable electronic apparatus and thus alter the appearance of the apparatus, and the functions provided by the coating according to the invention. The switch cover usually comprises fastening means that can be opened and closed, by means of which the cover can detachably be fastened to the frame of the portable electronic apparatus and/or to the cover of such an apparatus.

In one embodiment of the invention the cover is a cover for a mobile phone. This kind of a cover has one or more openings, through which actuators, such as key pad, display, microphone or speaker, in the frame of the mobile phone, can be operated from outside the cover.

In a typical embodiment of the invention DLC-coating and suitable plastic materials are used in such a novel way that by utilizing interference of light certain visual functions can be achieved in the coated part.

A thin non-metallic DLC-coating, i.e. a DLC-diamond film, achieved by means of the coating method according to the invention adheres firmly to the surface of the part to be coated.

With the aid of the invention non-metallic parts or products can be provided that, however, appear metallic. Typically a DLC-coating conducts electricity very poorly, usually being used as an electrical insulator. This is important for example in circumstances, in which electrical conductivity is desired to be avoided, such as in the cover for the antenna part of the mobile communications apparatus. However, by controlling the coating process in a certain manner the DLC-coating can be made to conduct electricity to a certain extent. For example, the cover for a portable electronic communications apparatus can be arranged to conduct electricity to a certain extent, for example for the purpose of ESD-protection. Thus, in this manner to a part or product to be coated an antistatic surface is achieved, which for example hinders the part or product from getting dirty.

A coating according to the invention can be fully made solely of coal. Coal is not detrimental to nature and is a biodegradable material. It is possible to make the coating very thin, whereby very small amounts thereof come on coated products. A small amount of coating according to the invention does not hinder the recycling of coated plastic parts, for example. In a coating method according to the invention environmentally hazardous additives or solvents are not required, which usually are necessary in conventional coating methods.

A coating according to the invention as well as parts and products coated therewith can be arranged to be easy to clean and to be durable and at the same time light in weight.

With the aid of the DLC-coating of the invention new properties can be chosen for the plastic cover of a portable electronic apparatus. The surface of the cover can be arranged antistatic by means of the new coating. The surface of the cover can be arranged hard but slippery, and thus wear resistant. The surface of the cover can also be arranged to have a good heat conductivity, for example in order to cool a certain section of the cover or to even out temperatures of a hot section. The DLC-coating is also easy to arrange on the cover in such a manner that it reflects heat radiation i.e. radiation energy away from the electronic apparatus being protected by the cover.

Reflecting surfaces can be arranged on the cover, for example a reflecting lens or window. In one embodiment of the invention a lens or window in an electronic apparatus is coated with a DLC-coating. In this manner windows and lenses in apparatuses can be for example hidden from the user, however so that the window or lens can be used normal fashion.

In one embodiment of the invention the DLC-coating can be arranged on top of an infrared window of an electronic apparatus. The DLC-coating allows the infrared radiation (IR) to pass through it. Because of its antistatic properties dust does not considerably build on a DLC-coating. Because of its evenness and slipperiness dirt does not considerably stick to a DLC-coating. Consequently, IR beams have access to the apparatus and away therefrom in a possibly unobstructed manner. Lenses or windows of all kinds of electronic apparatuses, such as those of a digital box, television or DVD player, can be coated with a DLC-coating. The IR beam leaving from a remote control or the IR beam coming into a remote controlled apparatus can be arranged to pass through a window coated with a DLC-coating.

According to the invention the material of the cover for a portable electronic apparatus coated with a DLC-coating can be chosen from the group of: PC (polycarbonate), ABS (acrylonitrile butadiene styrene copolyene), a PC/ABS mixture, polyamides, polyesthers.

A coating method according to the invention is typically performed at a relatively low temperature, for example at a temperature of 15-30° C. i.e. at approximately room temperature. Therefore, most polymers and thermoplastic elastomeres can be coated with it.

Typically the DLC-coating method is performed in a vacuum, and normally in a batch-type fashion. The DLC-coating apparatus can be arranged also to function semi-continuously and, if required, also completely continuously.

A typical DLC-coating according to the invention has a thickness of, for example, 20-500 nm, advantageously 20-120 nm and most advantageously 40-80 nm. In some cases, for example, if it is desired to make the DLC-coating according to the invention to have a good heat conductivity, the DLC-coating can be made even thicker, for example 500-5000 nm.

The cover can be made to appear to have a desired color depending on the thickness and other parameters of the coating method of the DLC-coating according to the invention. Said parameters are, for example, the type of microstructure formed on the DLC-coating. The microstructure can be, for example, amorphous or organized. The relationship between an amorphous and organized structure in a DLC-coating may vary, and by controlling this relationship the colors of the DLC-coating may be affected. Typical colors to be achieved by means of a DLC-coating are silver, gold, nacreous color, yellow, red, green and blue, all of them in several different shades. With a coating according to the invention special functions can be created depending on the colors chosen and on the shapes of the surface of the part to be coated. For example, certain functional parts of the cover for the portable communications apparatus, such as a certain function key or its surroundings, can be emphasized from the rest of the cover. In such a manner, for example, finding the power key in poor lighting conditions can be made easier.

In one embodiment of the invention a DLC-coating according to the invention is placed on an at least mainly transparent surface of a cover for a portable electronic communications apparatus, for example on the inner surface of the cover. The transparent cover accentuates colors providing a more vibrant appearance, even an appearance that gives three-dimensional impression. If the DLC-coating is on the inside of the cover, the cover protects the coating from wearing. Thus the coating can be made particularly thin.

According to the invention with a DLC-coating surface patterns can be achieved on the cover or other product to be coated by using a mask between a plasma source and the product to be coated.

The above-mentioned advantages of the invention are further emphasized if the outer surface of the cover intended to be visible and/or touched is at least partly of a DLC-coating according to the invention. At least a portion of the DLC-coated part of the cover can be protected by coating it with a suitable substance, such as a varnish protecting it from dents and scratches. If such a coating material protecting the DLC-coating is at least mainly transparent, the inventive visual functions of the cover can be maintained.

In one embodiment of the invention an IML-film (In Mould Labelling) is coated with a DLC-coating, which thereafter is placed in an injection mould for the cover according to the invention. This DLC-coated film can then be fastened to the cover by means of another IML-film. If the used IML-films are transparent, a cover is achieved, which has been coated with two transparent plastic films, between which a thin DLC-layer is arranged. By means of such a coating special visual functions are achieved. For example, as the refractive index of a diamond's light is great, by placing a transparent film or a corresponding transparent channel next to the DLC-layer, a light guide is simply and inexpensively achieved in the cover for a portable electronic apparatus, for instance a mobile phone.

IMD (In Mould Decoration) is a patterning method for plastic products manufactured by means of injection molding, in which method the patterning is performed in conjunction of injection molding. An IMD-product consists of two parts: the actual injection mould piece and a transferred image. The antistatic nature of the DLC-coating is advantageous in coating the plastic cover for an electronic apparatus by means of both the IML-method as well as the IMD-method.

In one embodiment of the invention a thin reflective layer, such as a metal layer, can be attached to an uncoated cover, onto which layer a DLC-coating according to the invention is then arranged. If said reflective layer is a metal layer, it may have a thickness of for example 10-5000 nm, advantageously 20-100 nm and most advantageously 20-40 nm. The metal can be selected, for example, from the group: titanium, stainless steel, aluminium, copper alloys.

The DLC-coating is easy to manufacture in such a manner that its crystal structure is very organized and that the degree of organization of the crystal structure can be controlled. Thus, the DLC-coating can also be arranged as a radiation shield. One way to utilize the DLC-coating is to use it as a UV-radiation shield. This is particularly suitable for parts of apparatuses to be used outdoors, such as for the protection of antennas for base stations of mobile communication networks.

As by means of DLC-coating according to the invention the cover and particularly the color of the cover for a portable electronic apparatus, such as a mobile phone, can be manufactured to be individual, complicated and difficult to copy, such a coating can be used as an authenticity label or a part thereof in different products.

In one aspect of the invention a circuit board or antenna is manufactured in such a manner that first a basic material, for example plastic is coated with a metal coating that the circuit board or antenna requires, for example, copper. The obtained circuit board or antenna can then be recoated with a DLC-coating. As the DLC-coating can be made not to conduct electricity and it can be arranged quite durable, the DLC-coating can be used to protect the circuit board and antenna from e.g. dust and humidity. It is usually necessary for these embodiments that the electrical insulation ability of the DLC-coating is carefully controlled. This can be done by observing and controlling the parameters of the coating process, particularly the microstructure of the DLC-coating. Such a circuit board and antenna can be, for example, functional parts of a portable electronic device, such as a mobile communications apparatus.

It is also possible to manufacture an antenna from DLC-coating so that the suitably electricity conducting DLC-coating can be used as material for the antenna. If it is desired, the antenna can also be formed from a combination of DLC-coating and some suitable metal.

### BRIEF DESCRIPTION OF THE FIGURES

The invention is described in more detail below with reference to the enclosed schematic drawing, in which

FIG. 1 shows a cover for a mobile communications apparatus according to the invention,

FIG. 2 shows a cross-section of the cover 1,

FIG. 3 shows a mobile communications apparatus according to the invention and a user thereof.

### DETAILED DESCRIPTION OF THE EXAMPLES OF THE FIGURES

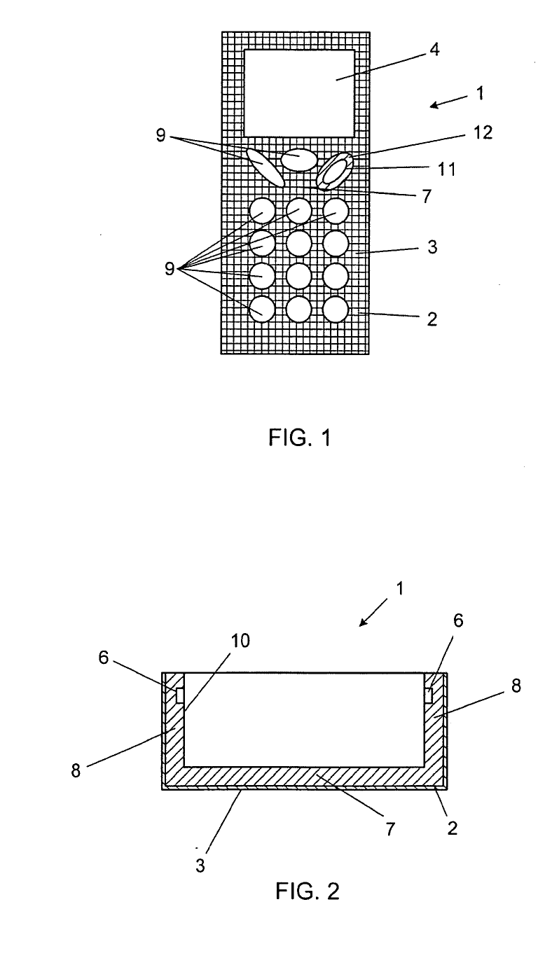

In FIGS. 1 and 2 a detachably fastenable cover 1, i.e. a so-called switch cover, to a mobile communications apparatus according to the invention is schematically shown. The cover comprises an outer surface 3, which is visible, when the cover 1 is fastened to the frame of the mobile phone (the frame is not shown in the figures). The outer surface 3 of the cover is entirely coated with a DLC-coating 2 according to the invention. The DLC-coating 2 covering the entire outer surface of the cover is formed uniform regarding its microstructure so that the entire area of the cover 1 has uniform surface properties, such as coloring and good wear resistance.

Cover 1 is a non-planar cover with thin walls having a mainly planar middle part 7 and side walls 8 protruding from said middle part. The cover 1 is designed in such a manner that the frame of the phone at least partly extends inside it. The dimensions of the cover vary according to the dimensions of the phone with which the cover 1 is intended to be used.

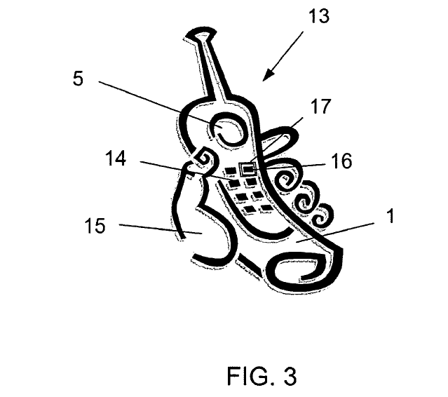

There is a first opening 4 for viewing the display 5 (FIG. 3) and numerous other openings 9, through which the function keys 14 (FIG. 3) of the phone fit freely. It is self-evident that the number of openings 9 may vary, and for example that if the cover is intended to be switch cover of the rear part of the phone, it is possible that there are no openings in the cover.

Means 6 are formed as one piece with the inner surface 10 of the side walls 8, with the aid of which means 6 the cover 1 can be detachably fastened to the frame with a snap coupling. Said means 6 are shown schematically, and their shape, number and position depend on the model of the phone and frame with which the cover 1 is to be used.

There is an opening 11 for the power key of the phone. The edges of the opening 11 are coated with a DLC-coating 12, which differs regarding its microstructure from the rest of the DLC-coating 2 of the cover. The coating 12 has been chosen so that the power key visually stands out from the other keys. Consequently, it is easy for a user to find the power key, for example, in poor lighting conditions. It is possible that the coating according to the invention is present only in certain parts of the cover, for example around one or several keys in the manner disclosed above.

In FIG. 3 a mobile phone 13 comprising the cover 1 is shown in the hand 15 of a user. The phone comprises a display 5 and several function keys 14. A DLC-coating 17 according to the invention is placed on the surroundings of a key 16, i.e. on the edge of the opening for the key. The coating 17 is formed in such a special manner that it can be used as an authenticity label for the phone 13 or switch cover 1.

Only some advantageous embodiments of the invention are shown in the figures. Facts of secondary importance regarding the main idea of the invention, facts known as such or evident for a person skilled in the art, such as power sources or support structures possibly required by the invention, are not separately shown in the figures. It is evident to the person skilled in the art that the invention is not limited exclusively to the examples described above, but that it can vary within the scope of the claims presented below. The dependent claims present some possible embodiments of the invention, and they are not to be considered to restrict the scope of protection of the invention as such.

1. Cover for an electronic apparatus, comprising a basic part and a coating attached thereto, wherein the coating comprises a DLC-coating.

2. Cover according to claim 1, wherein the basic part of the cover is of a non-metallic substance, for example plastic, elastomer, fabric or leather.

3. Cover according to claim 1, wherein the basic part of the cover is of metal.

4. Cover according to claim 1 wherein the cover is coated with a DLC-coating over a substantial area.

5. Cover according to claim 4 wherein the cover is coated with a DLC-coating at least over its one surface at least nearly completely.

6. Cover according claim 1 wherein at least a part of its DLC-coating is further coated with at least a mainly transparent substance.

7. Cover according to claim 1 wherein thickness of the DLC-coating is 20-500 nm.

8. Cover according to claim 1 wherein thickness of the DLC-coating is 0-120 nm.

9. Cover according to claim 1 wherein thickness of the DLC-coating is 40-80 nm.

10. Cover according to claim 1 comprising a lens or window, which is coated with the DLC-coating.

11. Cover according to claim 10, wherein the lens or window is an infrared beam window of a remote control or of a remote controlled apparatus.

12. Mobile communications apparatus comprising a cover according to claim 1.

13. Method for producing a coated cover for an electronic apparatus with coal plasma produced from solid graphite by means of arc discharge method, the method comprising at least following steps
accelerating coal plasma between two electrodes in order to provide a large amount of kinetic energy to coal ions
adhering the high-energy coal ions to the surface of the cover by penetrating the cover
forming by the coal ions on the surface of the cover an amorphous diamond structure, i.e. a DLC-coating.

14. Method according to claim 13, wherein the cover is coated at least over its one surface at least nearly completely with the DLC-coating.

15. Method according to claim 13, wherein before the coating
a polymer mixture is injection molded to form a cover to be coated.

16. Method according to claim 13, wherein the coating is performed at a temperature of 15-30° C.

17. Method according to claim 13, wherein the coating is performed in a vacuum.

18. Method according to claim 13, wherein the coating is performed in a batch-type fashion.

19. Method according to claim 13, wherein the coating is performed in a semi-continuous fashion.

20. Method according to claim 13, wherein the coating is performed in a continuous fashion.
